(19) United States
(12) Patent Application Publication
(10) Pub. No.: US 2014/0044873 A1
(43) Pub. Date: Feb. 13, 2014

(54) SINGLE-WALLED CARBON NANOTUBE (SWCNT) FABRICATION BY CONTROLLED CHEMICAL VAPOR DEPOSITION (CVD)

(71) Applicants: Makarand Paranjape, Silver Spring, MD (US); Marcio Fontana, Salvador (BR)

(72) Inventors: Makarand Paranjape, Silver Spring, MD (US); Marcio Fontana, Salvador (BR)

(21) Appl. No.: 13/572,285

(22) Filed: Aug. 10, 2012

(51) Int. Cl. C23C 16/26; B82Y 40/00

(52) U.S. Cl. 427/249.1; 118/721; 977/843

(57) ABSTRACT

The system and method disclosed herein provide a predetermined, variable volume argon-hydrogen gas mixture for a chemical vapor deposition (CVD)-based process, which enables the growth of single-walled carbon nanotube (SWCNT) structures. The exemplary SWCNT structures of this system and method are fabricated with a degree of control over the field emissions produced by the SWCNT and the range of diameters of each of the SWCNTs. Specifically, the predetermined diameter ranges and the field emissions of the SWCNT structure corresponds to a predetermined range of concentrations of the argon-hydrogen mixture and the argon concentration respectively. The defects and the diameter of the SWCNTs typically contribute to field emissions from the SWCNT structures at low applied voltages.

### TECHNICAL FIELD

The present disclosure relates to a system and method for fabricating single-walled carbon nanotube (SWCNT) structures comprised of either an individual SWCNT or multiple SWCNTs, such as meshes, by a controlled chemical vapor deposition process.

### BACKGROUND

A carbon nanotube (CNT) is a tubular structure made of carbon atoms with a diameter in the nanometer range. Single-walled carbon nanotubes (SWCNTs) typically have unique physical and chemical properties, and are useful in numerous potential applications in such areas as field emission displays, hydrogen storage, gas sensors, and electronics.

Chemical vapor deposition (CVD) is one method for fabricating SWCNTs structures. SWCNTs are typically fabricated from nanometer-sized metal particles, which enable hydrocarbon decomposition at a lower temperature than the spontaneous decomposition temperature of the hydrocarbon. The process involves flowing hydrocarbon vapor through a heated quartz tube.

The addition of the argon flow typically produces multi-walled carbon nanotubes (MWCNTs) in one-step by the catalytic CVD. Argon plasma produces an efficient etching and cleaning process on grown multiwall carbon nanotubes. Successful structural improvement in the MWCNTs has been obtained leading to an increase in the emission current and a reduction in the turn-on voltage for MWCNT structures. However, the introduction of a new gas entity in a typical CVD process can induce changes on morphological and physical properties of the SWCNTs.

### SUMMARY

The system and method described herein overcome the drawbacks discussed above by using a predetermined range of concentrations of argon-hydrogen gas mixture in a chemical vapor deposition (CVD)-based process to grow single-walled carbon nanotube (SWCNT) structures of predetermined ranges and with defects, wherein the SWCNT structures enable field emissions at low voltages, such as at 6.5 V/μm or below. The predetermined diameter ranges of the SWCNTs and the field emissions in the SWCNT structure corresponds to a predetermined range of concentrations of the argon-hydrogen mixture.

In an exemplary implementation, a method for fabricating Single-Walled Carbon Nanotubes (SWCNTs) is disclosed. A silicon dioxide (SiO₂) layer is formed on a wafer substrate using any method for growing, converting, or depositing a SiO₂ layer. In an exemplary implementation herein, the SiO₂ layer is applied by growing the SiO₂ using a dry-wet-dry oxidation process at a temperature of about 1100° C. for about 10 minutes on dry oxidation, about 70 minutes on wet oxidation, and about 10 minutes on dry oxidation. In an exemplary implementation, the method and system disclosed herein may utilize one or more chambers for applying a photoresist to the SiO₂-layered substrate and patterning the photoresist to create select and non-select areas by developing and removing the developed photoresist to expose the SiO₂ layer in select areas, while retaining the photoresist on the non-select areas. Examples of such chambers and process include, a spin-coating chamber to apply the photoresist; a lithography chamber for subjecting the photoresist to a photolithography process using optical lithography patterning and developing the patterned photoresist; and an etching chamber for applying a wet-etch process to remove or strip the developed resist layer from the select areas, thereby exposing the underlying SiO₂ layer in the select areas.

In another exemplary implementation, instead of the optical lithography application, the method and system disclosed herein may utilize one or more chambers for subjecting the photoresist to electron beam lithography development to retain and protect the non-select areas and expose the SiO₂ layer in the select areas. An exemplary photoresist that may be applicable in the electron beam lithography development is polymethylmethacrylate (PMMA).

The patterned substrate is then subject to a catalyst solution. In an example, such a catalyst solution may include ferric nitrate nonahydrate, dioxomolybdenum complex (MoO₂) with an acetylacetonate ligand, and aluminum oxide dissolved in methanol. In an exemplary implementation, the catalyst solution may be applied by a spin-casting process. A patterned catalyst is formed by removing the remaining photo-resist. The post-catalyzed substrate is then subjected to high-temperature baking in the presence of an inert argon gas flow. Further, the inert argon gas flow is continued till oxygen gas from the environment surrounding the post-catalyzed substrate is purged. The post-catalyzed substrate is then subject to a chemical vapor deposition process in a process chamber, where methane gas and a predetermined mixture of an argon gas and a hydrogen gas is provided into the process chamber for a predetermined duration of time. The predetermined mixture is varied by concentration of the argon gas to the hydrogen gas. Further, the variation of the concentration of argon gas-to-hydrogen gas corresponds to predetermined ranges of diameters for the fabricated SWCNTs, while the argon gas concentration enables generation of field emissions from the fabricated SWCNTs at an applied voltage of 6.5 volts per micrometer (V/μm) and below.

In an exemplary implementation, prior to subjecting the substrate to the catalyst solution, the substrate is cleaned using a combination of such process as an ultrasonic degreasing, a rinsing step, and a drying step. By way of an example, the ultrasonic degreasing may include a chemical cleaning solution of tricholoroethylene (C₂HCl₃), acetone ((CH₃)₂CO), and isopropyl alcohol (C₃H₈O). The rinsing step involves bathing the degreased substrate in deionized water, while in the drying step, the degreased substrate is dried in a nitrogen environment.

In an exemplary implementation, the high-temperature baking occurs in a three-zone temperature setting of 750° C. for one zone, 900° C. for a second zone, and 750° C. for a third zone. Further, in an example, the methane gas and the predetermined mixture of argon and hydrogen gases flow at a combined flow rate of 60 standard cubic centimeters per minute (sccm); and the predetermined duration of time for the predetermined mixture to flow is 30 minutes. In an exemplary implementation, the methane gas in the predetermined mixture is flowed at a fixed flow rate of 32 standard cubic centimeters per minute (sccm).

In another exemplary implementation, a system for fabricating Single-Walled Carbon Nanotubes (SWCNTs) is disclosed. The system may include one or more chambers, each designed for performing the functions disclosed. The system includes a chamber for applying a silicon dioxide (SiO₂) layer on the wafer substrate using such methods as growing, converting, or depositing. Typically, chemical vapor deposition (CVD) chambers are applicable to grow SiO₂ layers using the appropriate chemistry. Alternatively thermal oxidation is a method for laying down an SiO₂ layer by converting an underlying portion of the silicon substrate to SiO₂. As described above, the system includes one or more chambers for applying a photoresist and patterning the photoresist to create select and non-select areas, and to subsequently expose the SiO₂ layer in the select areas. The system includes a chamber for subjecting the patterned substrate to a catalyst solution. Typically, such a chamber may be a spin-cast or coating chamber, where the wafer is made to rotate at high speeds following a catalyst exposure step, and is subsequently dried. Further, the system as disclosed includes a process chamber for subjecting the post-catalyzed substrate to high-temperature baking in the presence of an inert argon gas flow. Such a chamber may also be a CVD chamber as previously described. The process chamber typically includes one or more valves for continuing the inert argon gas flow to purge oxygen gas from the environment surrounding the post-catalyzed substrate. After the purging step, the post-catalyzed substrate undergoes a chemical vapor deposition process, where each of the valves are adjusted for providing methane gas and a predetermined mixture of an argon gas and a hydrogen gas in the process chamber for a predetermined duration of time. The one or more valves are adjustable to vary the predetermined mixture by concentration of the argon gas to the hydrogen gas. Further, the variation of the concentration of argon gas-to-hydrogen gas corresponds to predetermined ranges of diameters for the fabricated SWCNTs, while the argon gas concentration enables generation of field emissions from the fabricated SWCNTs at an applied voltage of 6.5 volts per micrometer (V/μm) and below.

In yet another exemplary implementation, the system described above, may include one ore more chambers for cleaning the substrate prior to subjecting it to the catalyst solution. One such chamber may include ultrasonic capabilities, for an ultrasonic degreasing system for degreasing the substrate using tricholoroethylene (C₂HCl₃), acetone ((CH₃)₂CO), isopropyl alcohol (C₃H₈O). In the same chamber or a different chamber, a rinsing component is made available for rinsing the degreased substrate in deionized water. Finally, the same or a different chamber may support a drying step for drying the degreased substrate in a nitrogen environment.

In yet another exemplary implementation, the CVD chamber or a separate process chamber provides high-temperature baking functions via a three-zone temperature setting. The three-zone system enables uniform distribution of heat over the surface of the wafer. In an example, the settings for the three-zones may at temperatures of 750° C. for one zone, 900° C. for a second zone, and 750° C. for a third zone. Further the CVD chamber or the process chamber may include one or more valves for allowing the methane gas and the predetermined mixture of argon and hydrogen gases to flow in the process chamber at a combined flow rate of 60 standard cubic centimeters per minute (sccm); and time setting capabilities for setting the predetermined duration of time for the predetermined mixture to flow into the process chamber at 30 minutes. Another valve may be provided on the CVD chamber or the process chamber, where the valve is adjustable to control the flow of methane gas in the predetermined mixture at a fixed flow rate of 32 standard cubic centimeters per minute (sccm).

In an exemplary implementation, in the system and method disclosed herein, the argon gas concentration causes defects in the fabricated SWCNT and wherein these defects enable the generation of field emissions from the fabricated SWCNTs at the applied voltage of 6.5 volts per micrometer (V/μm) and below.

In another exemplary implementation, the method and system for fabricating SWCNTs disclosed herein, produces SWCNTs with specific emission current characteristics. Specifically, the SWCNTs fabricated at between 0 vol % to 50 vol % of argon concentration in the predetermined mixture produces field emissions at an emission current of 1.0 microampere (μA) for an applied voltage of between 6.5 Volts/μm to 4.5 Volts/μm respectively; and the SWCNTs fabricated at between 50 vol % to 90 vol % argon concentration in the predetermined mixture produces field emissions at an emission current of 1.0 microampere (μA) for an applied voltage of between 4.5 Volts/μm to 4.4 Volts/μm respectively.

In yet another exemplary implementation, the system and method disclosed herein results in predetermined range of diameters for the fabricated SWCNTs in the order of 1.0 nanometers (nm) to 2.2 nm when the variation of the concentration of argon gas-to-hydrogen gas in the predetermined mixture is 0-to-100 volume-percentage of argon gas-to-hydrogen gas; or 1.0 nm to 2.0 nm when the variation of the concentration of argon gas-to-hydrogen gas in the predetermined mixture is 25-to-75 volume-percentage of argon gas-to-hydrogen gas; or 1.1 nm to 1.5 nm when the variation of the concentration of argon gas-to-hydrogen gas in the predetermined mixture is 50-to-50 volume-percentage of argon gas-to-hydrogen gas; or in the range of 1.1 nm when the variation of the concentration of argon gas-to-hydrogen gas in the predetermined mixture is 75-to-25 volume-percentage of argon gas-to-hydrogen gas; or in the range of 1.1 nm when the variation of the concentration of argon gas-to-hydrogen gas in the predetermined mixture is 90-to-10 volume-percentage of argon gas-to-hydrogen gas.

### BRIEF DESCRIPTION OF THE DRAWINGS

The accompanying drawings constitute a part of this specification and together with the specification, illustrate certain exemplary embodiments of this disclosure.

FIG. 1 illustrates a method for fabricating single-walled carbon nanotube (SWCNT) structures using a controlled CVD process in accordance with an exemplary implementation.

FIG. 2 illustrates a system for fabricating SWCNT structures using a controlled CVD process in accordance with an exemplary implementation.

FIG. 3 illustrates a system for fabricating SWCNT structures using a controlled CVD process in accordance with an exemplary implementation.

FIGS. 4A and 4B are graphs illustrating Raman spectra charts of exemplary SWCNT structures fabricated by the method and system disclosed herein.

FIG. 5 is an intensity ratio bar chart for exemplary SWCNT structures fabricated by the method and system disclosed herein.

FIGS. 6A and 6B are test results for exemplary SWCNT structures fabricated by the method and system disclosed herein.

FIG. 7 is a collection of three scanning electron microscope (SEM) images, where each SEM shows a different range of diameters of the resulting exemplary SWCNT structures fabricated by the controlling the gas flow volumes in accordance with an exemplary implementation.

### DETAILED DESCRIPTION

Reference will now be made in detail to the preferred embodiments, examples of which are illustrated in the accompanying drawings.

The system and method disclosed herein provide a predetermined, variable rate and volume argon-hydrogen gas mixture for a chemical vapor deposition (CVD)-based process, which enables the growth of single-walled carbon nanotube (SWCNT) structures. The SWCNT structures of this system and method are fabricated with a degree of control over the range of diameters of each of the SWCNT in the SWCNT structure and field emissions characteristics, which are enabled low voltages for the SWCNT structure. Specifically, the diameter range and field emissions of the SWCNT fabricated in accordance with an exemplary implementation herein, corresponds to the predetermined range of concentrations, represented in volume-percentage, of the argon-hydrogen mixture. The field emissions are typically characteristic of the diameter and defect quality in the fabricated SWCNT structures.

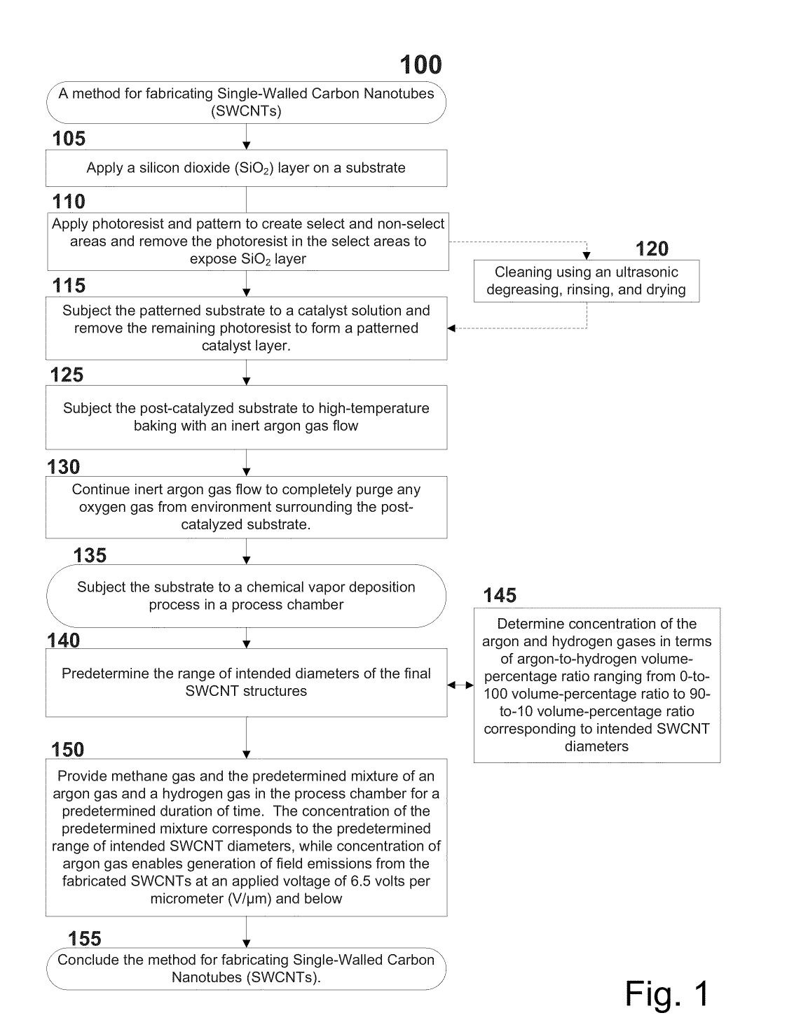

FIG. 1 illustrates a method 100 for fabricating single-walled carbon nanotube (SWCNT) structures using a controlled CVD process in accordance with an exemplary implementation. In an exemplary implementation, silicon wafers with the following characteristics may be used as a substrate in accordance with the system and method disclosed herein: p-type, orientation <100>, 500-550 μm thickness, and 0.001-0.005 Ω-cm resistivity. The terms ‘substrate’ and ‘wafer’ are used interchangeably herein to refer to the substrate that forms the base for fabrication of the SWCNT structures. Such substrates may be sourced from Nova Electronic Materials Limited. Further, even though subsequent exemplary processing steps are described as performed on the substrate, such as, a cleaning or a baking step, it is understood by one skilled in the art that, the term “substrate” following prior processing steps may include one or more layers formed by prior process, such as, an SiO₂ layer, a catalyst layer, etc. Block 105 illustrates a step where a thin silicon dioxide (SiO₂) layer is grown or layered on the wafer. Typically, a furnace chamber utilizes a dry-wet-dry oxidation process at a temperature of 1100° C. for 10 min, 70 min, and 10 min respectively, to grow the SiO₂ layer. The term “Chamber” as used herein refers to containers, vessels, or designated areas, both open or closed, where the processing steps, transfer, and storage of the wafer or substrates disclosed herein occurs. Other methods for forming a SiO₂ layer may include, converting an underlying silicon layer to SiO₂ or depositing a SiO₂ layer via CVD processes in such devices as a hot-wall CVD reactor; both of these methods are applicable to the disclosure herein.

At block 110, a photoresist is applied to the SiO₂-layered substrate. The photoresist is patterned to create non-select and select areas using optical lithography or electron beam lithography (EBL), and thereafter, using etching or EBL to expose the SiO₂ layer in the select areas. In an exemplary implementation, the SiO₂-layered substrate is subject to a positive photoresist solution applied by spin-coating. After a short pre-baking step, the photoresist and a photomask are exposed to a pattern of ultraviolet (UV) light for about 10 seconds. Accordingly, such photomasks may be applicable to select areas for stripping or removing of the photoresist layer from select areas to expose the underlying SiO₂ layer. A positive photoresist may then be exposed to a developer solution for development. A wet-etch process may be used to remove the developed resist and expose the SiO₂ layer. Alternatively, the photoresist is subject to electron beam lithography development to protect the non-select areas and expose the SiO₂ layer in the select areas, while retaining the photoresist in the non-select areas. The substrate-based SWCNTs fabricated by the exemplary method and system herein provide the appropriate field emissions current at low applied voltages.

Thereafter, block 115 illustrates the use of a chamber for spin-casting or depositing a catalyst solution onto the patterned substrate. In an exemplary implementation, the catalyst solution includes 1.6 mg of ferric nitrate nonahydrate; 0.5 mg of a precursor dioxomolybdenum complex (MoO₂) with a acetylacetonate ligand, chemically represented as MoO₂.(acac)₂, where acac is a acetylacetonate ligand complex; and about 15 mg of aluminum oxide dissolved in 20 ml of methanol. A patterned catalyst is formed by removing the remaining photo-resist to form a patterned catalyst layer. The silicon samples were subject to baking, illustrated in block 125, in a chamber with a three zone temperature furnace, in the presence of an inert argon gas flow. The temperature settings for the zones are typically in the range of 750° C. for zone 1, 900° C. for zone 2, and 750° C. for zone 3. Further, in block 130, the inert argon gas flow is continued to purge the oxygen from the environment around the post-catalyzed substrate, in the furnace tube. Subsequently, at block 135, SWCNT processing begins in a processing chamber, such as a chemical vapor deposition (CVD) chamber. The furnace chamber of blocks 125-130 may be a separate chamber or a part of the CVD chamber. In the SWCNT processing stages, at block 140, a determination is made as to the intended range of diameters for the final SWCNT structures.

The step of block 145 is typically related to block 140, where a determination is made as to the concentration of the argon-hydrogen gases from a range of 0-to-100 volume-percentage to 90-to-10 volume-percentage, depending on the intended diameter of the SWCNT structures. At block 150, valves on the processing chamber are automatically or manually adjusted to allow methane gas and the predetermined mixture of argon gas and hydrogen gas to flow into the processing chamber. The total flow rate is typically maintained at 60 standard cubic centimeters per minute (sccm) for a predetermined duration, such as 30 minutes, during the carbon nanotube growth. Further, concentration of argon gas enables generation of field emissions from the fabricated SWCNTs at an applied voltage of 6.5 volts per micrometer (V/μm) and below. Accordingly, the method and system disclosed herein is applicable to fabricating SWCNTs with predetermined ranges of diameters and predetermined ranges of applicable voltages for generating field emissions.

In an exemplary embodiment, the predetermined mixture corresponds to the predetermined range of diameters for the SWCNT structures. By way of an example, the methane flow is kept constant at 32 sccm, while different argon-to-hydrogen volume percentage concentrations are used, ranging from 0:100 vol % to 90:10 vol %. This is illustrated with reference to a determination step performed in block 145. Table 1 in this disclosure provides exemplary values of diameter ranges corresponding to the exemplary concentrations of argon-to-hydrogen gases used during fabrication. Block 155 concludes the method for fabricating single-walled carbon nanotube (SWCNT) structures using a controlled CVD process in accordance with an exemplary implementation.

In an exemplary implementation, ultrasonic degreasing is applied to the substrate, illustrated as block 120, to clean the substrate prior to applying the catalyst. Here, a closed chamber environment provides the ultrasonically degreasing processes for the silicon wafer. Ultrasonic degreasing typically utilizes chemicals, such as a solution of trichloroethylene (C₂HCl₃), acetone ((CH₃)₂CO) and isopropyl alcohol (C₃H₈O) to clean the substrate. Thereafter, the substrate is rinsed in deionized water and dried in nitrogen. The cleaned substrate proceeds to the spin-casting step for catalytic disposition as described above.

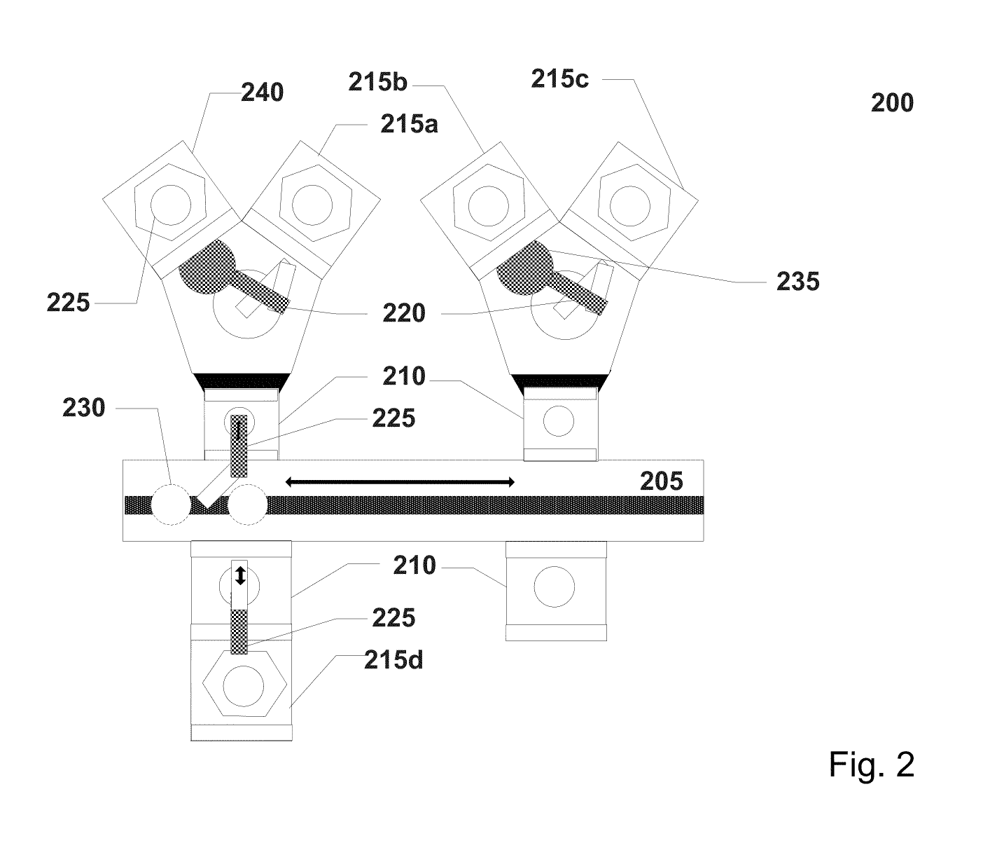

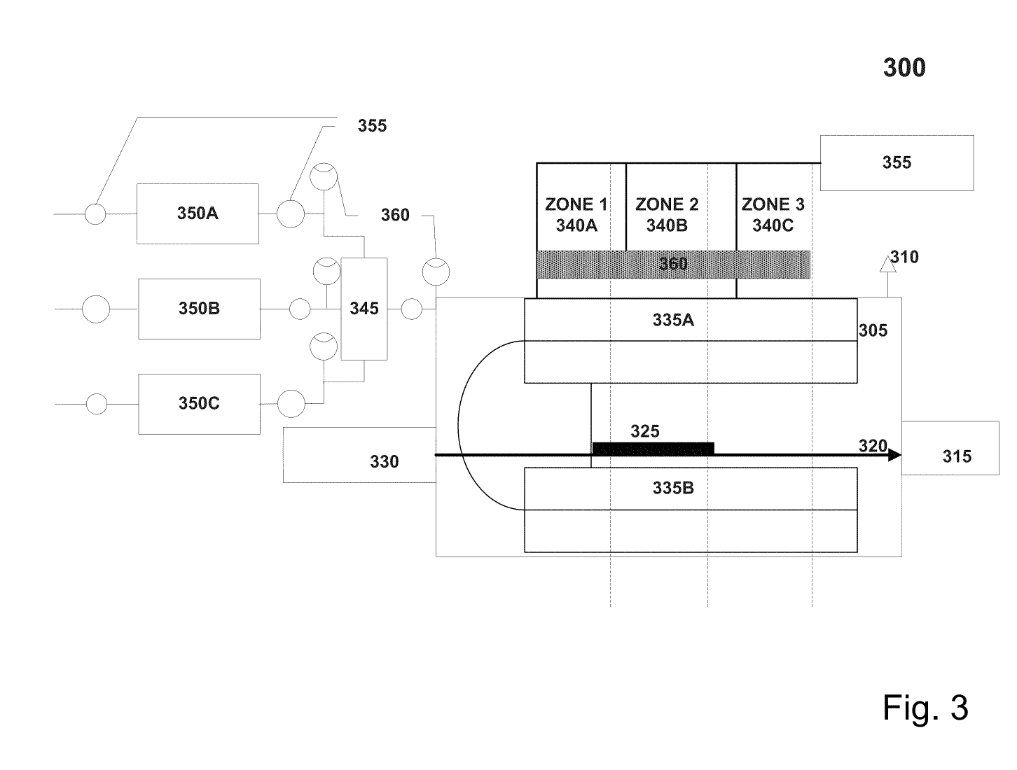

FIGS. 2 and 3 illustrate systems 200 and 300 for fabricating single-walled carbon nanotube (SWCNT) structures using a controlled CVD process in accordance with an exemplary implementation. The exemplary system of FIG. 2 includes multiple chambers, each designed to perform one or more functions as described with respect to FIG. 1, above, for growing SWCNT structures on the semiconductor wafer by controlled CVD. System 200 may include one ore more conveyance mechanisms 205, such as a conveyer belt, robotic arms, or a manual transfer mechanism, each designed to move wafers across chambers. By way of an example, wafers may be transferred from one chamber 215a to other such chambers 215b-c for processing. Such a transfer may be exposed to the atmosphere of the clean room encompassing the system 200 or may be a system under vacuum, such as 205. Chambers 210 may be load lock chambers or transfer chambers with robotic arms 225 for longitudinal transfers to and from the chambers. Load lock chambers are typically maintained at intermediate vacuum pressure during transfer from one processing station to another. Robotic arms 220 may function to transfer the wafers, shown as shaded areas 235, from one chamber to another within the same pressure setting.

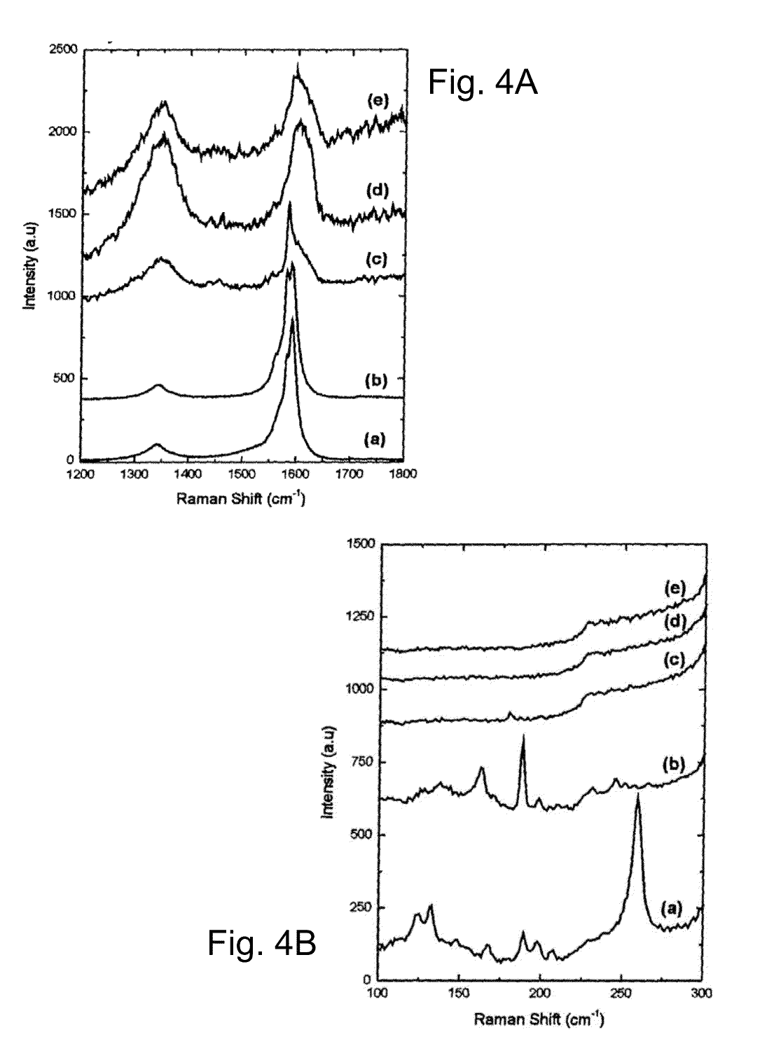

In an exemplary embodiment, the oxidation step for forming the SiO₂ layer on the silicon substrate may occur in the same chamber as the CVD steps to grow the SWCNT structures. However, there is a significant cleaning step required to remove residues and chemical deposits on the chamber walls, prior to the next step using a different set of gases. Further, the chamber needs to support a variety of gasses and processes. Alternatively, a three-zone furnace chamber, separate from the CVD processing chamber, is applicable to performing the oxidation growth step for the SiO₂ layer. The exemplary arrangement in FIG. 4 may represent an assembly line in accordance with an exemplary embodiment. Accordingly, lithography, etching, and spin-coating may occur in a pre-defined collection of chambers, such as 240 and 215a, thereby minimizing exposure of the wafer prior to stable completion of part of the fabrication processes. While SiO₂ layer growth may occur via a thermal oxidation chamber set up in chamber 215c, for instance.

In an exemplary implementation, the SiO₂-layered substrate is subject to a positive photoresist solution applied by spin-coating. Such a process can occur in a chamber that may be subject to vacuum transfers and is configured for lithography. After a short pre-baking step, the lithography chamber is used to provide the photoresist and to expose the photoresist in the presence of a photomask and a pattern of ultraviolet (UV) light for about 10 seconds. Accordingly, such photomasks may be applicable to select areas for stripping or removing of the photoresist layer from select areas to expose the underlying SiO₂ layer. A positive photoresist may then be exposed to a developer solution for development. Following this, an etching chamber, such as exemplary chamber 215a or 240, may be used to provide a wet-etching step, to remove the developed resist and expose the SiO₂ layer. Alternatively, the photoresist is subject to electron beam lithography development in an appropriate chamber based on the exemplary arrangement from FIG. 2 to protect the non-select areas and expose the SiO₂ layer in the select areas. The substrate-based SWCNTs fabricated by the exemplary method and system herein provide the appropriate field emissions current at low applied voltages.

A second spin-casting or coating process for applying the catalyst over the exposed SiO₂ layer on the substrate typically occurs at this stage, in an independent chamber, for example, chamber 215d. Thereafter, the remaining photoresist is removed from the post-catalyzed wafer and a patterned catalyst layer is left. This post-catalyzed wafer or substrate is transferred to the CVD machine, for example, chambers 215b-c, for the next processing step. Here, to limit exposure of the wafer after each processing step, it may be beneficial to transfer the wafer in a vacuum environment to chambers designed to be next to each other. Alternatively, conveyance 205 is applicable to transfer the wafer from one chamber area to another under vacuum. Element 230 illustrates individual wafers being transferred for processing in the pre-requisite chambers. Further, a cassette of wafers may be transferred from one processing step to the next based on the type of manufacturing—batch processing or continuous processing. An ultrasonic degreasing chamber, may be incorporated as one of the chambers 215 for cleaning the wafer prior to the spin casting chamber.

FIG. 3 illustrates, in greater detail, an exemplary processing chamber 305 of system 300 for fabricating single-walled carbon nanotube (SWCNT) structures using a controlled CVD process in accordance with an exemplary implementation. The chamber 305 includes input for a gas mixture from mixing source 345. Alternatively, the chamber may incorporate separate inputs for each of the gas sources 350A-C fed directly into the chamber 305. 350A-C represent the sources for each of the methane, hydrogen, and argon gases required to grow the SWCNT structures. Flow indicators 360 monitor the flow of gases through the system. Structures similar to 360 are implied to illustrate flow indicators in this disclosure. Valves 355 control the flow of gases into the mixing source 345 and may be automatically or manually set, based on the flow monitor outputs, in predetermined positions according to the predetermined range of diameters intended for the SWCNT structures. Structures similar to 355 are implied to illustrate valves in this disclosure. The flow rate is maintained to meet both the sccm rate and volume-percentage concentration requirements. In the case that the sources 350 is fed directly to the chamber 305, then the valves control the direct flow. In accordance with an exemplary implementation, an wafer 325 is placed on the wafer holder in the chamber 305 and subject to high temperature baking via element 360, which provides three zones 340A-C of different temperatures for baking the wafer. Heating controls 355 provide corrections required to maintain the temperature during processing. This enables an even surface temperature across the wafer. The wafer is also moved from input load lock 330 to output load lock 315. Alternatively, the wafer may be loaded and removed from the same side 330. 335A-B is a quartz tube that is heated during the initial process and holds the wafer during the SWCNT growth process. At the same time, inert argon is first flowed into the chamber. The inert argon purges any oxygen from the chamber in the environment of the wafer 325. 310 is an exhaust for gaseous by-products of the process.

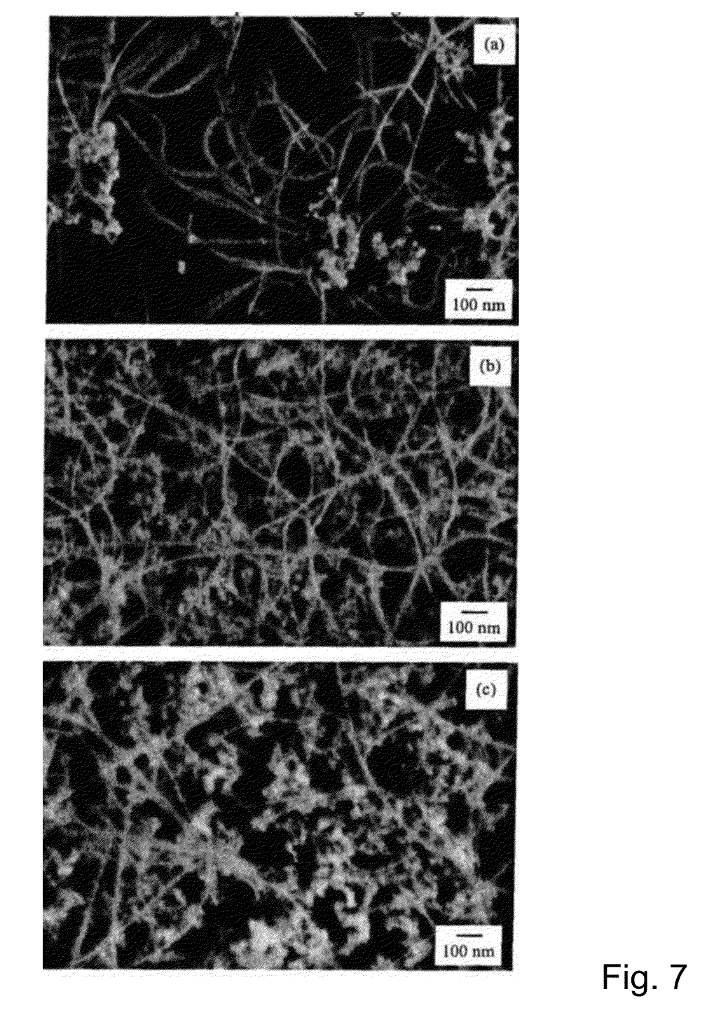

In accordance with the method and system disclosed herein, SWCNT samples fabricated with argon concentrations ranging from 0 vol % to 90 vol % were analyzed by FESEM and Raman spectroscopy. Surface morphology of some fabricated layers, in accordance with the method and system of this disclosure, was examined by FESEM using a Zeiss® Microscope. FIG. 7 is a collection of some of these SEM images. Further, Micro-Raman spectroscopy was carried out at room temperature using a RENISHAW in Via Raman® Microscope, employing the output of an Ar+ laser (20 mW power) for excitation at λ=514.5 nm. The characterization of field emission properties was performed in a specially designed vacuum fixture. A vacuum of 5×10-5 Torr was maintained during the measurements. A LabVIEW® software program was implemented in an IEEE-488 environment using a computer to set the Model 237 Source-Measure Unit (SMU) produced by Keithley Instruments Inc. The field emission measurements were performed at room temperature. The Raman spectra results are subject of FIGS. 4A-B of this disclosure.

FIGS. 4A and 4B are graphs illustrating Raman spectra charts of exemplary SWCNT structures fabricated by the method and system disclosed herein. FIG. 4A shows two typical SWCNT peaks located at 1350 cm-1 (D-band) and 1590 cm-1 (G-band) of the Raman spectra. The D-band and G-band are understood to one skill in the art as common characteristics of the Raman spectroscopy method of analysis. Also shown are two weak peaks in the features, at 1581 cm-1 (curves (a), (b) and (c)) and 1568 cm-1 (curves (d) and (e)), which are characteristics respectively of the metallic and semiconducting SWCNT structures. FIG. 4A illustrates that argon in the CVD furnace influences the layer conductivity of the SWCNT samples fabricated by the exemplary system and method disclosed herein. Accordingly, the exemplary system and method disclosed herein for fabricating SWCNTs will allow one to change the characteristic of the SWCNT between metallic to semiconducting.

FIG. 4B illustrates typical Radial Breathing Mode (RBM) peaks ranging from 100 to 300 cm⁻¹ which may be used to estimate the diameter of SWCNT. An exemplary sample produced in hydrogen-rich mixtures, with a lower argon concentration of less than 25 vol % typically has different RBM peaks. For example, curves (a) and (b) of FIG. 4B indicate higher diameter distribution, while the samples produced in hydrogen-poor mixtures, with a higher argon concentration of greater than 25 vol %, presented only a smooth peak. The smooth peak is illustrated via curves (c), (d) and (e) of FIG. 4B. Curves (c), (d) and (e) of FIG. 4B indicate regular diameter distribution of SWCNTs diameters. Table 1 shows details of the diameter distribution of SWCNTs synthesized at different argon concentrations in the furnace. The diameter distribution of the carbon nanotubes ranges between 1.0 nm and 2.2 nm depending on the different argon concentrations. Using argon provides smaller diameters as compared with those when pure hydrogen is used. Varying the argon to hydrogen concentrations from 0:100 vol % to 90:10 vol % changes the diameter distribution to lower values. These distributions corroborates well with data gathered from experiments conducted according to the exemplary system and method disclosed herein, where carbon nanotube diameter distribution was also found to decrease in the presence of argon gas.

TABLE 1
THE DIAMETER DISTRIBUTION OF SWCNTS
SYNTHESIZED AT ARGON CONCENTRATION.

| Argon:Hydrogen | | | |
|---|---|---|---|
| concentrations | RMB bands | Diameters | Relative intensity |
| (Vol %) | (cm⁻¹) | (nm) | of the RMB |
| 0:100 | 124 | 2.2 | w |
| | 133 | 2.1 | m |
| | 148 | 1.8 | w |
| | 167 | 1.6 | m |
| | 189 | 1.4 | m |
| | 198 | 1.3 | w |
| | 208 | 1.2 | w |
| | 259 | 1.0 | s |
| 25:75 | 137 | 2.0 | w |
| | 162 | 1.7 | m |
| | 188 | 1.4 | s |
| | 198 | 1.3 | w |
| | 231 | 1.1 | w |
| | 245 | 1.0 | w |
| 50:50 | 179 | 1.5 | w |
| | 229 | 1.1 | w |
| 75:25 | 229 | 1.1 | w |
| 90:10 | 229 | 1.1 | w |

Legend: w: weak, m: medium and s: strong

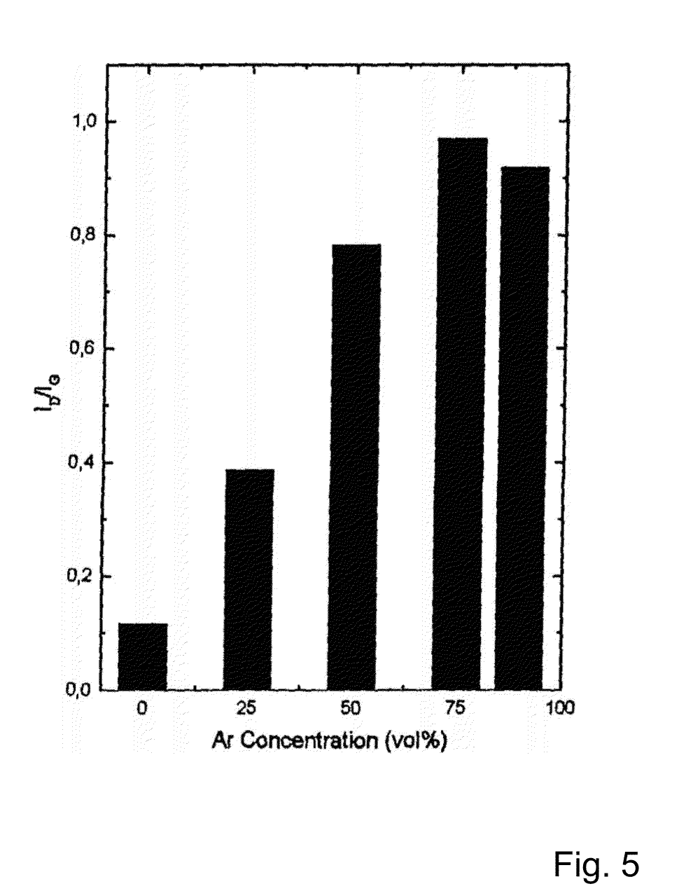

FIG. 5 is an intensity ratio (I_{D}:I_{G}) bar chart for exemplary SWCNT structures fabricated by the method and system disclosed herein. Specifically, FIG. 5 illustrates typical intensity ratio of D-band to G-band (I_{D}/I_{G}). In an exemplary implementation, the I_{D}/I_{G} ratio for fabricated samples was proportionally related to the argon concentration in the gas mixture. Fabricated SWCNT samples in accordance with the system and method of the present disclosure show intensity ratio of D-band to G-band ranging from 12% to 92% for different argon-to-hydrogen concentrations, ranging from 0:100 vol % to 90:10 vol %. In addition, at higher argon concentrations of about 75 vol % to 90 vol %, the intensity ratio of D-band to G-band shows no significant change, with ratios of 97% and 92%. These distributions corroborate well with data gathered from experiments conducted according to the exemplary system and method disclosed herein, where the disorder in sp² hybridized carbon networks is similar to the in-plane oscillation of carbon atoms in the sp² graphite sheet of SWCNTs.

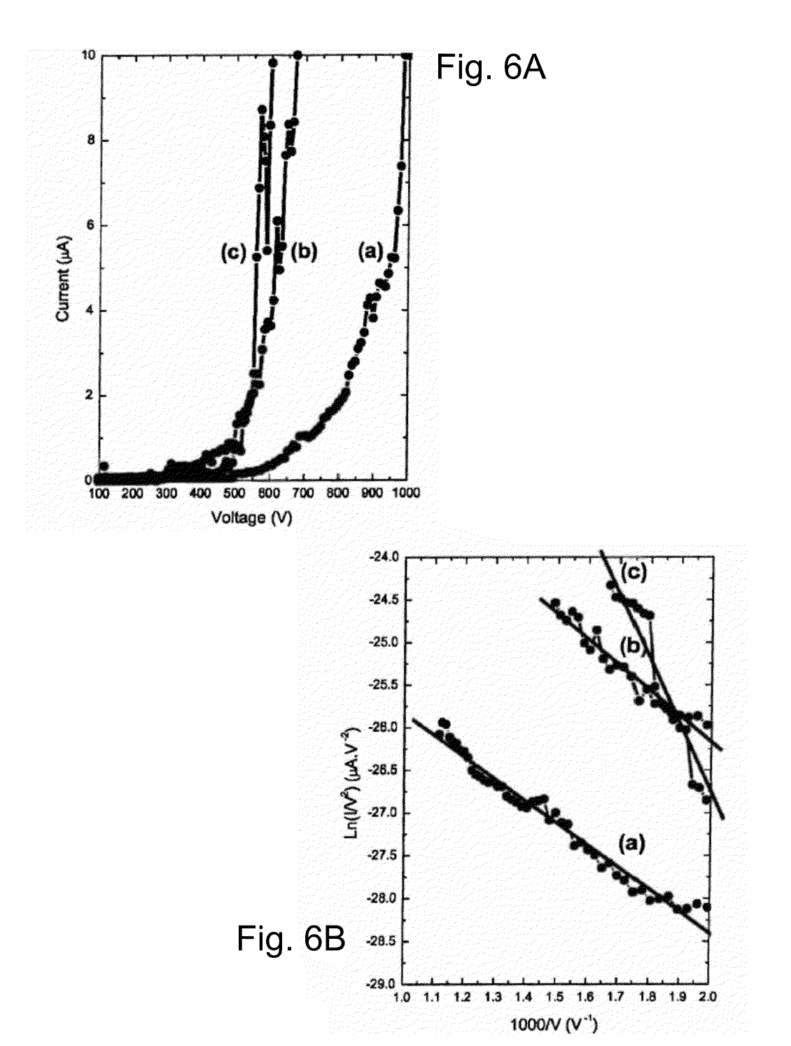

FIGS. 6A and 6B are test results for exemplary SWCNT structures fabricated by the method and system disclosed herein. Specifically, FIG. 5 illustrates typical current-voltage characteristic curves of synthesized samples, each fabricated in accordance with the system and method disclosed here and using different concentrations of argon. In an exemplary implementation, an increase in argon concentration in the gas mixture resulted in a corresponding decrease in the threshold voltage necessary to initiate field emission. This behavior may be typical dependence of the electric field enhancement factor that increases according to the cathode radius of curvature at the point of emission where the SWCNT diameter decreases. The onset electrical field for a detected emission current of 1.0 microampere (μA) for 0 vol %, 50 vol %, and 90 vol % argon concentration occurs at 6.5, 4.5, and 4.4 V/μm, respectively. Further, in samples fabricated herein, tests representative of oscillations were measured in the electron currents like “turn on-turn off” for higher argon concentrations. Accordingly, for fabricated SWCNT of the disclosure herein, the emissions may result from the body of the fabricated SWCNTs. The use of low temperatures in the CVD process, such as that of the exemplary temperatures in the steps disclosed above, in combination with the gas ratios, provide a level of control in terms of how the SWCNTs are formed and how they react on application of low voltage to cause desired field emissions. Typically, the defects favor local field emissions during the application of a voltage. These emissions are further augmented by the diameter of the formed SWCNT structures and the interaction of neighboring structures. Accordingly, the method and system disclosed herein allows fabrication of SWCNT with defects on the outer wall of the SWCNTs. The SWCNTs thus fabricated typically cause field emissions at lower voltages, such as, from 6.5 volts per micrometer (V/μm) or below, at 4.4 V/μm or below. In an exemplary implementation, the variation of the concentration of argon gas-to-hydrogen gas corresponds to SWCNTs fabricated with predetermined diameter ranges and with defects that produce field emissions at an emission current of 1.0 microampere (μA) for an applied voltage of 6.5 volts per micrometer (V/μm) or below.

FIG. 7 is a collection of three scanning electron microscope (SEM) images, where each SEM shows a different predetermined diameter ranges of the resulting exemplary SWCNT structures fabricated by the controlling the gas flow volumes in accordance with an exemplary implementation. The figure illustrates typical top-view FESEM images of synthesized samples produced by the CVD process disclosed herein. The method and system of this disclosure result in fabricated SWCNT structures, where an increase in argon concentration in the predetermined mixture of gases typically result in a corresponding decrease in the diameter of SWCNT.

The system and method of this disclosure may typically be used to grow in-plane SWCNT meshes using CVD by controlling the hydrogen-argon gas mixture. Raman spectroscopy measurements performed for the fabricated SWCNT structures in accordance with the exemplary implementations herein demonstrate that SWCNT produced with different argon concentrations in the process chambers may typically have different diameter distributions. Further, SWCNTs that typically display good field emission characteristics were fabricated using CVD with a methane/hydrogen/argon mixture. The threshold voltage-to-electron emission typically decreased with higher argon concentrations, possibly due to higher layer conductivity of the samples.

The exemplary methods and acts described in the embodiments presented previously are illustrative, and, in alternative embodiments, certain acts can be performed in a different order, in parallel with one another, omitted entirely, and/or combined between different exemplary embodiments, and/or certain additional acts can be performed without departing from the scope and spirit of the disclosure. Accordingly, such alternative embodiments are included in the disclosures described herein.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

What is claimed is:

1. A method for fabricating Single-Walled Carbon Nanotubes (SWCNTs) comprising:
applying a silicon dioxide (SiO₂) layer on a substrate;
applying a photoresist to the SiO₂-layered substrate;
patterning the photoresist to create select and non-select areas by developing the photoresist and removing the developed photoresist to expose SiO₂ layer in the select areas;
subjecting the patterned substrate to a catalyst solution and removing the remaining photoresist to form a patterned catalyst layer;
subjecting the post-catalyzed substrate to high-temperature baking in the presence of an inert argon gas flow;
continuing the inert argon gas flow to purge oxygen gas from the environment surrounding the post-catalyzed substrate; and
subjecting the substrate to a chemical vapor deposition process in a process chamber to fabricate SWCNTs comprising:
providing methane gas and a predetermined mixture of an argon gas and a hydrogen gas in the process chamber for a predetermined duration of time, wherein the predetermined mixture is varied by concentration of the argon gas to the hydrogen gas, and wherein
the variation of the concentration of argon gas-to-hydrogen gas corresponds to predetermined ranges of diameters for the fabricated SWCNTs, while the argon gas concentration enables generation of field emissions from the fabricated SWCNTs at an applied voltage of 6.5 volts per micrometer (V/μm) and below.

2. The method of claim 1, wherein the predetermined ranges of diameters for the fabricated SWCNTs are:
1.0 nanometers (nm) to 2.2 nm when the variation of the concentration of argon gas-to-hydrogen gas in the predetermined mixture is 0-to-100 volume-percentage of argon gas-to-hydrogen gas; or
1.0 nm to 2.0 nm when the variation of the concentration of argon gas-to-hydrogen gas in the predetermined mixture is 25-to-75 volume-percentage of argon gas-to-hydrogen gas; or
1.1 nm to 1.5 nm when the variation of the concentration of argon gas-to-hydrogen gas in the predetermined mixture is 50-to-50 volume-percentage of argon gas-to-hydrogen gas; or
in the range of 1.1 nm when the variation of the concentration of argon gas-to-hydrogen gas in the predetermined mixture is 75-to-25 volume-percentage of argon gas-to-hydrogen gas; or
in the range of 1.1 nm when the variation of the concentration of argon gas-to-hydrogen gas in the predetermined mixture is 90-to-10 volume-percentage of argon gas-to-hydrogen gas.

3. The method of claim 1, wherein the SiO₂ layer is applied by growing the SiO₂ using a dry-wet-dry oxidation process at a temperature of about 1100° C. for about 10 minutes on dry oxidation, about 70 minutes on wet oxidation, and about 10 minutes on dry oxidation.

4. The method of claim 1, wherein the catalyst solution is a solution of ferric nitrate nonahydrate, dioxomolybdenum complex (MoO₂) with a acetylacetonate ligand, and aluminum oxide dissolved in methanol.

5. The method of claim 1, wherein the catalyst solution is applied by a spin-casting process.

6. The method of claim 1, further comprising:
prior to subjecting the substrate to the catalyst solution, cleaning the substrate, wherein cleaning includes:
ultrasonic degreasing of the substrate using tricholoroethylene (C₂HCl₃), acetone ((CH₃)₂CO), isopropyl alcohol (C₃H₈O);
rinsing the degreased substrate in deionized water; and
drying the degreased substrate in a nitrogen environment.

7. The method of claim 1, wherein high-temperature baking occurs in a three-zone temperature setting of 750° C. for one zone, 900° C. for a second zone, and 750° C. for a third zone.

8. The method of claim 1, wherein the methane gas and the predetermined mixture of hydrogen and argon gases flow at a combined flow rate of 60 standard cubic centimeters per minute (sccm).

9. The method of claim 1, wherein the predetermined duration of time for the predetermined mixture to flow is 30 minutes.

10. The method of claim 1, wherein the methane gas in the predetermined mixture is flowed at a fixed flow rate of 32 standard cubic centimeters per minute (sccm).

11. The method of claim 1, wherein
the SWCNTs fabricated at between 0 vol % to 50 vol % of argon concentration in the predetermined mixture produces field emissions at an emission current of 1.0 microampere (μA) for an applied voltage of between 6.5 Volts/μm to 4.5 Volts/μm respectively; and
the SWCNTs fabricated at between 50 vol % to 90 vol % argon concentration in the predetermined mixture produces field emissions at an emission current of 1.0 microampere (μA) for an applied voltage of between 4.5 Volts/μm to 4.4 Volts/μm respectively.

12. The method of claim 1, wherein the argon gas concentration causes defects in the fabricated SWCNT and wherein these defects enable the generation of field emissions from the fabricated SWCNTs at the applied voltage of 6.5 volts per micrometer (V/μm) and below.

13. The method of claim 1, wherein patterning the photoresist to create select and non-select areas comprises:
subjecting the photoresist to photolithography development to protect the non-select areas and expose the SiO₂ layer in the select areas; and
applying a wet-etch to remove the developed photoresist layer from the select areas, thereby exposing the SiO₂ layer in the select areas.

14. The method of claim 1, wherein patterning the photoresist to create select and non-select areas comprises:
subjecting the photoresist to electron beam lithography development to protect the non-select areas and expose the SiO₂ layer in the select areas.

15. The method of claim 14, wherein the photoresist is polymethylmethacrylate (PMMA).

16. A system for fabricating Single-Walled Carbon Nanotubes (SWCNTs) comprising:
a chamber for applying a silicon dioxide (SiO₂) layer on a substrate;
a chamber for applying a photoresist to the SiO₂-layered substrate;
one or more chambers for patterning the photoresist to create select and non-select areas by developing the photoresist and removing the developed photoresist to expose the SiO₂ layer in the select areas;
one or more chambers for subjecting the patterned substrate to a catalyst solution and for removing the remaining photoresist to form a patterned catalyst layer;
a process chamber for subjecting the post-catalyzed substrate to high-temperature baking in the presence of an inert argon gas flow;
the process chamber including one or more valves for continuing the inert argon gas flow to purge oxygen gas from the environment surrounding the post-catalyzed substrate; and
the process chamber for subjecting the substrate to a chemical vapor deposition process to fabricate SWCNTs comprising:
one or more valves for providing methane gas and a predetermined mixture of an argon gas and a hydrogen gas in the process chamber for a predetermined duration of time, wherein the one or more valves are adjustable to vary the predetermined mixture by concentration of the argon gas to the hydrogen gas, and wherein
the variation of the concentration of argon gas-to-hydrogen gas corresponds to predetermined ranges of diameters for the fabricated SWCNTs, while the argon gas concentration enables generation of field emissions from the fabricated SWCNTs at an applied voltage of 6.5 volts per micrometer (V/μm) and below.

17. The system of claim 16, wherein the predetermined ranges of diameters for the fabricated SWCNTs are:
1.0 nanometers (nm) to 2.2 nm when the variation of the concentration of argon gas-to-hydrogen gas in the predetermined mixture is 0-to-100 volume-percentage of argon gas-to-hydrogen gas; or
1.0 nm to 2.0 nm when the variation of the concentration of argon gas-to-hydrogen gas in the predetermined mixture is 25-to-75 volume-percentage of argon gas-to-hydrogen gas; or
1.1 nm to 1.5 nm when the variation of the concentration of argon gas-to-hydrogen gas in the predetermined mixture is 50-to-50 volume-percentage of argon gas-to-hydrogen gas; or
in the range of 1.1 nm when the variation of the concentration of argon gas-to-hydrogen gas in the predetermined mixture is 75-to-25 volume-percentage of argon gas-to-hydrogen gas; or
in the range of 1.1 nm when the variation of the concentration of argon gas-to-hydrogen gas in the predetermined mixture is 90-to-10 volume-percentage of argon gas-to-hydrogen gas.

18. The system of claim 16, wherein the chamber in which SiO₂ layer is applied utilizes a dry-wet-dry oxidation process at a temperature of about 1100° C. for about 10 minutes on dry oxidation, about 70 minutes on wet oxidation, and about 10 minutes on dry oxidation.

19. The system of claim 16, wherein the chamber in which the catalyst solution is applied utilizes a catalyst solution of ferric nitrate nonahydrate, dioxomolybdenum complex (MoO₂) with a acetylacetonate ligand, and aluminum oxide dissolved in methanol.

20. The system of claim 16, wherein the chamber in which the catalyst solution is applied utilizes a spin-casting process.

21. The system of claim 16, further comprising:
a chamber for cleaning the substrate prior to subjecting it to the catalyst solution, wherein the cleaning chamber includes:
an ultrasonic degreasing system for degreasing the substrate using tricholoroethylene (C₂HCl₃), acetone ((CH₃)₂CO), isopropyl alcohol (C₃H₈O);
a rinsing component for rinsing the degreased substrate in deionized water; and
a drying chamber for drying the degreased substrate in a nitrogen environment.

22. The system of claim 16, wherein the process chamber provides high-temperature baking in a three-zone temperature setting, with temperatures of 750° C. for one zone, 900° C. for a second zone, and 750° C. for a third zone.

23. The system of claim 16, wherein the process chamber includes one or more valves for allowing the methane gas and the predetermined mixture of hydrogen and argon gases into the process chamber at a combined flow rate of 60 standard cubic centimeters per minute (sccm).

24. The system of claim 16, wherein the process chamber includes time setting capabilities for setting the predetermined duration of time for the predetermined mixture to flow into the process chamber at 30 minutes.

25. The system of claim 16, wherein the process chamber includes a valve to adjust the methane gas in the predetermined mixture to flow at a fixed flow rate of 32 standard cubic centimeters per minute (sccm).

26. The system of claim 16, wherein
the SWCNTs fabricated at between 0 vol % to 50 vol % of argon concentration in the predetermined mixture produces field emissions at an emission current of 1.0 microampere (μA) for an applied voltage of between 6.5 Volts/μm to 4.5 Volts/μm respectively; and
the SWCNTs fabricated at between 50 vol % to 90 vol % argon concentration in the predetermined mixture produces field emissions at an emission current of 1.0 microampere (μA) for an applied voltage of between 4.5 Volts/μm to 4.4 Volts/μm respectively.

27. The system of claim 16, wherein the argon gas concentration causes defects in the fabricated SWCNT and wherein these defects enable the generation of field emissions from the fabricated SWCNTs at the applied voltage of 6.5 volts per micrometer (V/μm) and below.

28. The system of claim 16, wherein patterning the photoresist to create select and non-select areas comprises:
subjecting the photoresist to photolithography development to protect the non-select areas and expose the SiO₂ layer in the select areas; and
applying a wet-etch to remove the developed photoresist layer from the select areas, thereby exposing the SiO₂ layer in the select areas.

29. The system of claim 16, wherein patterning the photoresist to create select and non-select areas comprises:
subjecting the photoresist to electron beam lithography development to protect the non-select areas and expose the SiO₂ layer in the select areas.

30. The system of claim 16, wherein the photoresist is polymethylmethacrylate (PMMA).
